(19) United States
(12) Patent Application Publication
(10) Pub. No.: US 2001/0053601 A1
(43) Pub. Date: Dec. 20, 2001

(54) Method of manufacturing MIS semiconductor device that can control gate depletion and has low resistance gate electrode to which germanium is added

(76) Inventor: Toru Mogami, Tokyo (JP)

Correspondence Address: McGinn & Gibb, PLLC, Suite 200, 8321 Old Courthouse Road, Vienna, VA, 22182-3817, US

(21) Appl. No.: 09/850,033

(22) Filed: May 8, 2001

(30) Foreign Application Priority Data
May 11, 2000 (JP) 2000-138092

(51) Int. Cl. H01L 21/44; H01L 21/4763

(52) U.S. Cl. 438/658; 438/682; 438/655; 438/649; 438/664

(57) ABSTRACT

According to a method of manufacturing a MIS semiconductor device of the present invention, a gate insulating film is formed on a silicon substrate, and a silicon thin film is deposited on the gate insulating film, whereafter a silicon film containing germanium is deposited on the silicon thin film and an amorphous silicon film is deposited on the germanium-containing silicon film. Further, heat treatment is performed to diffuse the germanium in the germanium-containing silicon film into the silicon thin film, and a metal film is deposited on the amorphous silicon film and heat treatment is performed to cause a silicidation reaction to occur with the metal film to form a silicide film. Therefore, the germanium-containing silicon film which can control gate depletion can be formed stably with a good reproducibility. Further, since the silicide film on the gate electrode is formed on the silicon film, it can be formed with a low resistance.

### BACKGROUND OF THE INVENTION

1. Field of the Invention

This invention relates to a method of manufacturing a MIS semiconductor device, and more particularly to a method of manufacturing a MIS field effect transistor having a gate electrode to which germanium (Ge) is added.

2. Description of the Relates Art

Conventionally, a transistor which uses a polycrystalline silicon film doped with impurities by ion implantation as a gate electrode that contacts with a gate insulating film suffers from depletion in a region in the proximity of a portion of the polycrystalline silicon film at which it contacts with the gate insulating film because the impurities are not doped by a sufficiently great amount in the polycrystalline silicon film. The depletion increases the effective thickness of the gate insulating film, and this gives rise to a problem of deterioration of the transistor performance. This problem is more serious particularly where the transistor is so refined that the gate length is smaller than 0.25 μm and the thickness of the gate insulating film is smaller than approximately 6 nm. This is because the influence of the gate depletion increases as the thickness of the gate insulating film decreases. Thus, a transistor structure wherein a silicon-germanium film which is less likely to suffer from depletion is used as a gate electrode has been proposed (for example, Technical Digest of the 1998 Symposium on VLSI Technology, pp. 190-191, Jun. 7, 1998: document 1). Recent CMOS devices use, as a structure for obtaining a gate electrode of a lower resistance, a salicide structure which is obtained by forming a germanium-containing polycrystalline silicon gate electrode first and then causing a silicidation reaction to occur between the silicon and the metal film to form a low resistance silicide film (for example, Technical Digest of the 1999 International Electron Devices Conference, pp. 427-430, Dec. 7, 1999: document 2).

When a silicon-germanium film doped with impurities in order to control the depletion of the gate electrode is used as a gate electrode, where the gate insulating film is a silicon oxide base insulating film, difficulty occurs in that a silicon-germanium film having a desired composition cannot be deposited well by germanium film growth or silicon-germanium film growth based on a chemical vapor phase growth method which uses germane (CH4 or the like) gas. This is because germane gas is not likely to react on the gate insulating film as described also, for example, in “1992 Japanese Journal of Applied Physics”, Vol. 31, pp. 1432-1435, 199: document 3. In order to eliminate the difficulty described above, a method of forming a silicon-germanium film by a physical vapor phase growth method is disclosed in Japanese Patent Laid-Open No. 3999/1999. However, it is difficult to apply the physical vapor phase growth method to formation of a gate electrode of a transistor because it is inferior in film coverage to the chemical vapor phase growth method. Furthermore, formation of an intermetallic compound, which is low in junction leakage and low in resistance, through reaction between a germanium film or a silicon-germanium film and a metal film is difficult with cobalt which is conventionally adopted widely as described also in document 2 above.

### SUMMARY OF THE INVENTION

It is an object of the present invention to provide a method of manufacturing a MIS semiconductor device that can control gate depletion and has a low resistance gate electrode to which germanium is added.

The present invention has been made based on a result of an examination wherein a silicon film doped with impurities and a germanium-silicon film doped with impurities were used for a gate electrode or a result of another examination wherein a multilayer structure of a silicon film doped with impurities and a germanium-silicon film doped with impurities was used for a gate electrode. The relationship of the gate depletion of a transistor to the germanium concentration in a case wherein a silicon film doped with impurities was used for a gate electrode and another case wherein a germanium-silicon film doped with impurities was used for a gate electrode is illustrated in FIG. 1. From FIG. 1, it can be seen that the gate depletion can be reduced by raising the germanium concentration.

Meanwhile, the relationship of the sheet resistance of an intermetallic compound to the germanium concentration in a case wherein a silicon film doped with impurities or a germanium-silicon film doped with impurities is used as an undercoat layer to form a low resistance intermetallic compound with a metal film is illustrated in FIG. 2. From FIG. 2, it can be seen that the resistance of the intermetallic compound (metal silicide) as the germanium concentration increases.

Further, the relationship between the germanium concentration and the film deposition rate on a silicon oxide film is illustrated in FIG. 3. It can be seen that, on a silicon oxide film, the film deposition rate is extremely low due to a high concentration of germanium. On the other hand, as recited in “Applied Physics”, Vol. 60, No. 11, 1991, pp. 1123-1126: document 4, particularly on ten lines following “3. Selective Growth”, the right column of page 1124, on silicon, the film deposition rate little depends upon the germanium concentration.

Table 1 indicates the diffusion rate of germanium into silicon in a multilayer structure of a silicon film and a germanium-silicon film. From Table 1, it can be seen that the diffusion rate of germanium is high where the silicon particle size of a polycrystalline silicon film is small, but where the silicon particle size of a polycrystalline silicon film is large or where an amorphous silicon film is used, the diffusion rate is low. Accordingly, it is an effective method which achieves both of reduction of gate depletion and reduction of the resistance to use a silicon film of a small particle size for a lower layer conductor film, use a germanium-silicon film for an intermediate conductor film and use a silicon film of a large particle size for an upper layer conductor film and diffuse germanium into the lower layer silicon film by heat treatment.

According to the present invention, a silicon-germanium film is deposited on a silicon film on a gate insulating film and germanium is diffused from the silicon-germanium film into the silicon film. Therefore, a silicon-germanium film that can control gate depletion can be formed stably and with a high degree of reproducibility.

Further, since a silicide film on a gate electrode is formed on a silicon film, a silicide film of a low resistance can be formed while a silicon-germanium film is used as a gate electrode material.

Furthermore, according to a concrete example wherein heat treatment for germanium diffusion is performed after three layer films including a silicon film, a silicon-germanium film and an amorphous silicon film or a large particle size silicon film are formed, germanium can be diffused only into the lower layer silicon film. Consequently, an improved productivity can be achieved and the two effects described above can be enjoyed.

The above and other objects, features and advantages of the present invention will become apparent from the following description with reference to the accompanying drawings which illustrate examples of the present invention.

### BRIEF DESCRIPTION OF THE DRAWINGS

FIG. 1 is a graph illustrating a relationship between the germanium concentration in a silicon-germanium film and the gate depletion rate;

FIG. 2 is a graph illustrating a relationship between the germanium concentration in a silicon-germanium film and the sheet resistance of a silicide film formed by reaction with a metal film;

FIG. 3 is a graph illustrating a relationship between the deposition time and the deposited film thickness upon formation of a silicon-germanium film where the germanium content is used as a parameter;

FIG. 4 is a sectional view of successive steps illustrating a first embodiment and a first concrete example of the present invention;

FIG. 5 is a sectional view of successive steps illustrating a second concrete example of the present invention;

FIG. 6 is a sectional view of successive steps illustrating a third concrete example of the present invention;

FIG. 7 is a sectional view of successive steps illustrating a fourth concrete example of the present invention;

FIG. 8 is a sectional view of successive steps illustrating a second embodiment and a fifth concrete example of the present invention;

FIG. 9 is a sectional view of successive steps illustrating a sixth concrete example of the present invention;

FIG. 10 is a sectional view of successive steps illustrating a seventh concrete example of the present invention; and

FIG. 11 is a sectional view of successive steps illustrating an eighth concrete example of the present invention.

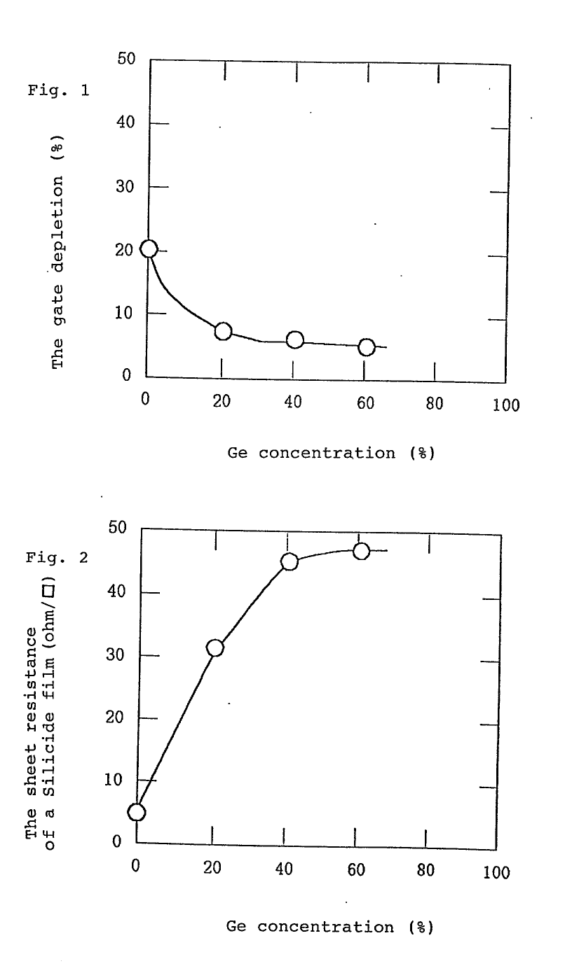

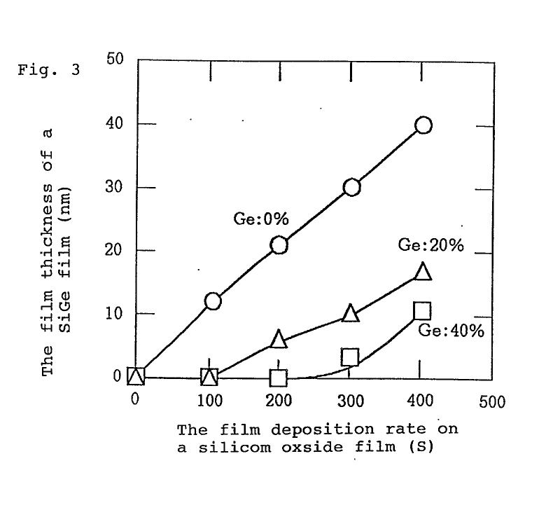

### DETAILED DESCRIPTION OF THE PREFERRED EMBODIMENTS

### First Embodiment

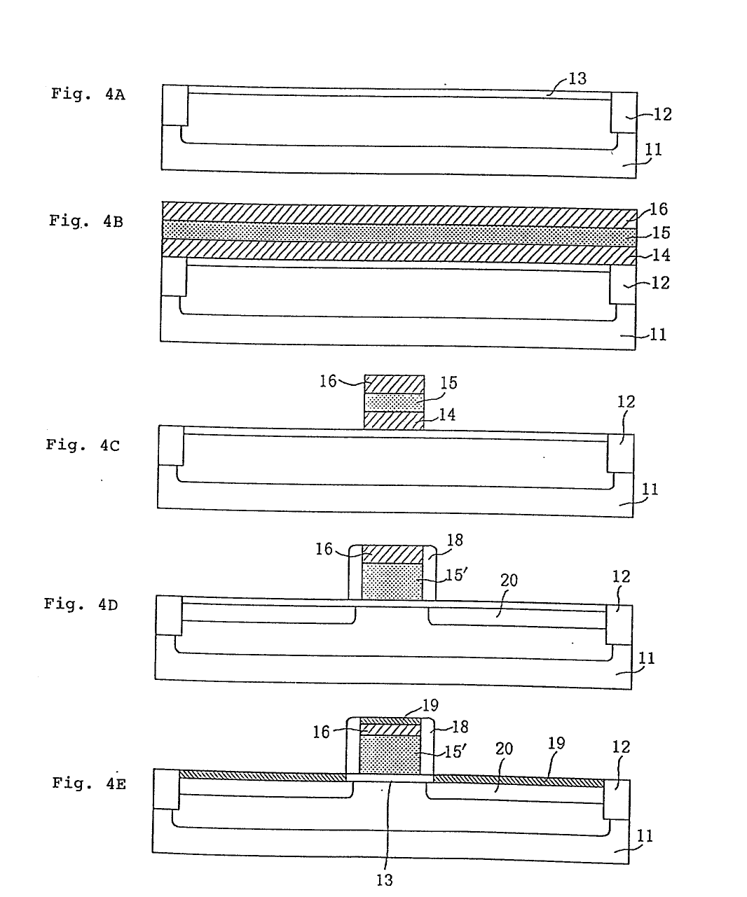

FIGS. 4A to 4E are sectional views of successive steps illustrating a first embodiment of the present invention.

First, as shown in FIG. 4A, gate insulating film 13 of a silicon oxide base, for example, is formed on silicon substrate 11 on which element isolation region 12 is formed.

Then, as shown in FIG. 4B, silicon film 14 of 2 to 20 nm thick is formed as a first layer conductive film by chemical vapor phase growth, in which silane gas or disilane gas is used, on the silicon substrate.

On the first layer conductive film, germanium-silicon film 15 of 20 to 100 nm thick whose germanium concentration is 5 to 50% is deposited as a second layer conductive film by chemical vapor phase growth in which silane gas or disilane gas and germane gas are used.

Then, amorphous silicon film 16 of 20 to 100 nm thick is formed as a third layer conductive film on the second layer conductive film by chemical vapor phase growth.

Preferably, silicon film 14 is formed from polycrystalline silicon, and besides the particle size of the polycrystalline silicon is preferably smaller than the film thickness. Further, preferably the first to third layer conductive films are formed successively in the same chamber, and further preferably, the movement between the formation step of gate insulating film 13 and the formation step of the first layer conductive film is performed under vacuum.

Then, as shown in FIG. 4C, the layered first, second and third layer conductive films are worked into a gate electrode shape by an ordinary lithography step and etching step.

Thereafter, as shown in FIG. 4D, a CVD silicon oxide film is deposited as a cover film on the surface of the substrate, and germanium in the second layer conductive film is diffused into the first layer conductive film by heat treatment of 600 to 1000° C. to form silicon-germanium film 15′.

Furthermore, the CVD silicon oxide film is etched back to form gate electrode sidewalls 18. Then, impurities are doped into the surface of the silicon substrate and the gate electrode by ordinary ion implantation. Furthermore, heat treatment is performed to activate the impurities to convert the gate electrode into a conductor and form source-drain regions 20.

Thereafter, as shown in FIG. 4E, a metal film such as a titanium film or a cobalt film is deposited by 1 to 10 nm. Then, metal silicide film 19 is formed in a self-aligning state on the source-drain regions and the gate electrode by heat treatment, and the unreacted metal film is removed, thereby completing the manufacturing process of the MIS transistor according to the present invention.

### First Concrete Example

Next, a first concrete example of the present embodiment will be described with reference to FIGS. 4A to 4E.

As shown in FIG. 4A, element isolation region 12 is formed on silicon substrate 11 by shallow trench, and a silicon nitride oxide film of 2 nm thick is formed as gate insulating film 13 by a thermal oxide nitriding method or CVD.

Then, as shown in FIG. 4B, silicon film 14 of 10 nm thick is deposited as a first layer conductive film by ordinary CVD, and germanium-silicon film 15 of 50 nm thick containing 30% germanium is deposited as a second layer conductive film on silicon film 14. Further, amorphous silicon film 16 of 100 nm thick is deposited as a third layer conductive film on germanium-silicon film 15. Germanium-silicon film 15 was deposited by a CVD method in which silane gas or disilane gas and germane gas were used. Amorphous silicon film 16 was deposited at a temperature lower than 550° C. by CVD.

Then, as shown in FIG. 4C, the first to third conductive films are patterned to form a gate electrode by an ordinary lithography step and etching step.

Thereafter, as shown in FIG. 4D, a silicon oxide film or a silicon nitride film is deposited by 8 nm on the surface of the substrate by CVD, and then, heat treatment at 800° C. is performed for 30 minutes to diffuse germanium in the second layer conductive film into silicon film 14 of the first layer conductive film to form silicon-germanium film 15′.

Further, the CVD silicon oxide film or silicon nitride film is etched back to form gate electrode side walls 18, and impurities such as arsenic, phosphor or boron are doped by approximately 5×10¹⁵ cm⁻² into the gate electrode and the surface of the substrate by ordinary ion implantation. Furthermore, heat treatment for a short time at 1000° C. is performed to activate the impurities to reduce the resistance of the gate electrode and form source-drain regions 20.

Then, as shown in FIG. 4E, a titanium film is deposited by 5 nm by sputtering, and metal silicide film (titanium silicide film) 19 is formed in a self-aligning manner on the source-drain regions and the gate electrode by heat treatment for a short time at 700° C. Further, the unreacted metal film is removed by wet etching, thereby completing the manufacturing process of the MIS transistor of the present concrete example.

While, in the present concrete example, titanium is used as the metal for the silicide formation, the metal is not limited to titanium, and some other metal such as cobalt may be used instead.

### Second Concrete Example

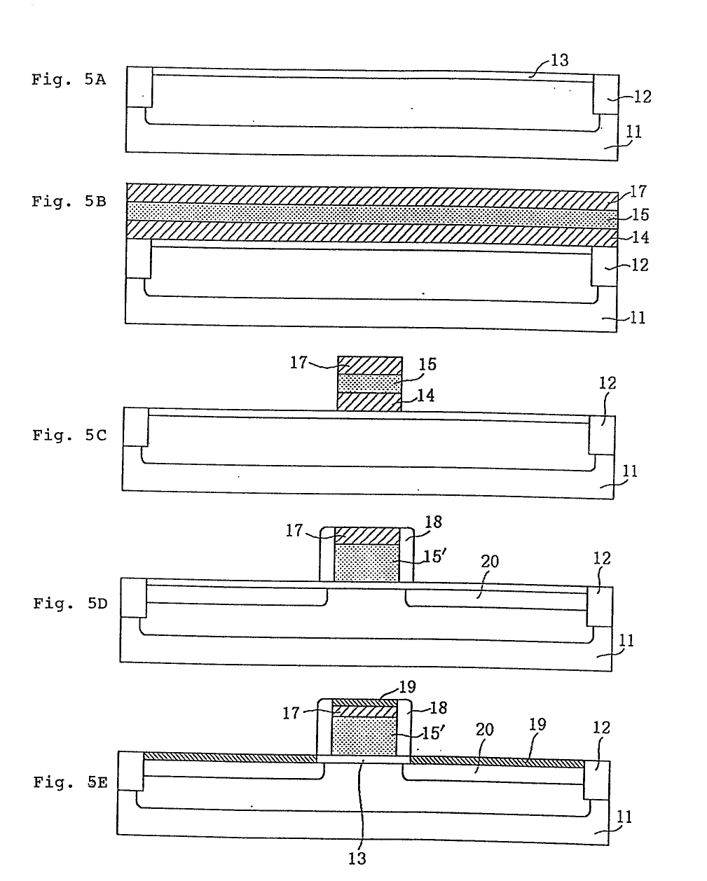

FIGS. 5A to 5E are sectional views of successive steps illustrating a second concrete example of the present embodiment.

As shown in FIG. 5A, element isolation region 12 is formed on silicon substrate 11 by shallow trench, and a silicon nitride oxide film of 1 nm thick is formed as gate insulating film 13 by a radical oxide nitriding method.

Then, as shown in FIG. 5B, silicon film 14 of 5 nm thick is deposited as a first layer conductive film by ordinary CVD, and germanium-silicon film 15 of 50 nm thick containing 20% germanium is deposited as a second layer conductive film on silicon film 14. Further, large particle size silicon film 17 of 100 nm thick is deposited as a third layer conductive film on germanium-silicon film 15. Germanium-silicon film 15 was deposited by CVD in which silane gas or disilane gas and germane gas were used. Large particle size silicon film 17 was deposited by CVD at a temperature higher than 600° C. The film thickness of large particle size silicon film 17 is preferably 20 to 100 nm, and besides, the particle size of large particle size silicon film 17 is preferably greater than the film thickness.

Then, as shown in FIG. 5C, a gate electrode pattern is formed by an ordinary lithography step and etching step.

Thereafter, as shown in FIG. 5D, a silicon oxide film or a silicon nitride film is deposited by 5 nm on the surface of the substrate by CVD, and then, heat treatment at 800° C. is performed for 30 minutes to diffuse germanium in the second layer conductive film into silicon film 14 of the first layer conductive film to form silicon-germanium film 15′.

Further, the CVD silicon oxide film or silicon nitride film is etched back to form gate electrode side walls 18, and impurities such as arsenic, phosphor or boron are doped by approximately 3×10¹⁵ cm⁻² into the gate electrode and the surface of the substrate by ordinary ion implantation. Furthermore, heat treatment for a short time at 1000° C. is performed to activate the impurities to reduce the resistance of the gate electrode and form source-drain regions 20.

Then, as shown in FIG. 5E, a cobalt film is deposited by 5 nm by sputtering, and metal silicide film (cobalt silicide film) 19 is formed in a self-aligning manner on the source-drain regions and the gate electrode by heat treatment for a short time at 600 to 700° C. Further, the unreacted metal is removed by wet etching, thereby completing the manufacturing process of the MIS transistor of the present example.

While, in the present concrete example, arsenic, phosphor or boron is used as the impurities to be doped into the gate electrode and the source-drain regions, the impurities need not be limited to them, but some other impurities such as indium or antimony may be used instead.

### Third Concrete Example

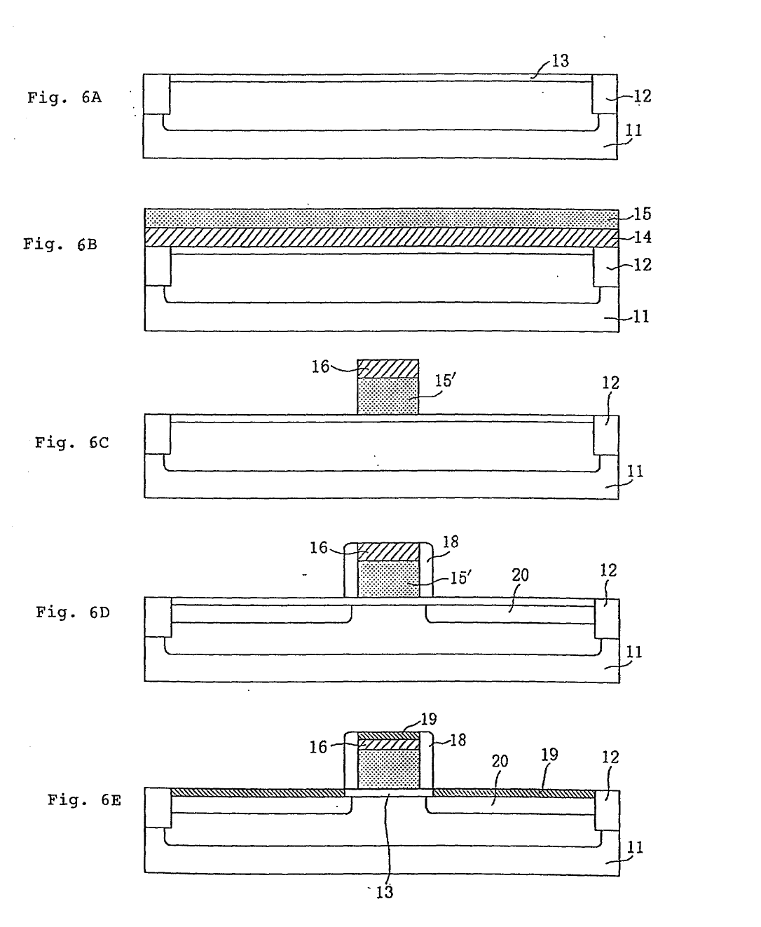

FIGS. 6A to 6E are sectional views of successive steps illustrating a third concrete example of the present embodiment.

First, as shown in FIG. 6A, element isolation region 12 is formed on silicon substrate 11 by shallow trench, and a silicon nitride oxide film of 0.5 nm thick is formed as gate insulating film 13 by a radical oxide nitriding method. Then, a tantalum pentoxide (Ta2O5) film is deposited to 2 nm thick on the silicon nitride oxide film by CVD, and further, a silicon oxide film of 0.5 nm thick is deposited on the tantalum pentoxide film by CVD.

Then, as shown in FIG. 6B, silicon film 14 of 5 nm thick is deposited as a first layer conductive film by ordinary CVD. Further, germanium-silicon film 15 of 50 nm thick containing 40% germanium is deposited as a second layer conductive film on silicon film 14. Germanium-silicon film 15 was deposited by CVD in which silane gas or disilane gas and germane gas were used.

Then, as shown in FIG. 6C, silicon-germanium film 15′ is formed by heat treatment by an ordinary heat treatment step at approximately 800° C., and amorphous silicon film 16 of 100 nm thick is deposited by low temperature CVD. Thereafter, the deposited conductive films are patterned into a shape of a gate electrode by an ordinary lithography step and etching step.

Then, as shown in FIG. 6D, a silicon oxide film or a silicon nitride film is deposited by 5 nm on the surface of the substrate by CVD, and then, it is etched back to form gate electrode side walls 18. Further, impurities such as arsenic, phosphor or boron are doped by approximately 5×10¹⁵ cm⁻² into the gate electrode and the surface region of the substrate by ordinary ion implantation. Furthermore, heat treatment for a short time at 1000° C. is performed to activate the impurities to reduce the resistance of the gate electrode and form source-drain regions 20.

Then, as shown in FIG. 6E, a cobalt film is deposited by 5 nm by sputtering, and metal silicide film 19 is formed in a self-aligning manner on the source-drain regions and the gate electrode by heat treatment for a short time at 600 to 700° C. Further, the unreacted metal film is removed by wet etching, thereby completing the manufacturing process of the MIS transistor of the present example.

While, in the present concrete example, a silicon nitride oxide film, a tantalum pentoxide film and a silicon oxide film are used for the gate insulating film layer structure, the gate insulating film layer structure is not limited to them, but aluminum oxide, zirconium oxide, hafnium oxide, lanthanum oxide, titanium oxide, barium strontium titanate (BST) or the like may be used for the high dielectric constant film of the medium layer. Also it is possible to omit the silicon oxide film. Furthermore, it is possible to use a silicon oxide film in place of the silicon nitride oxide film or use a silicon nitride oxide film in place of the silicon oxide film. Also it is possible to use a layered gate insulating film including a high dielectric constant film in place of the gate insulating film of the other concrete examples.

### Fourth Concrete Example

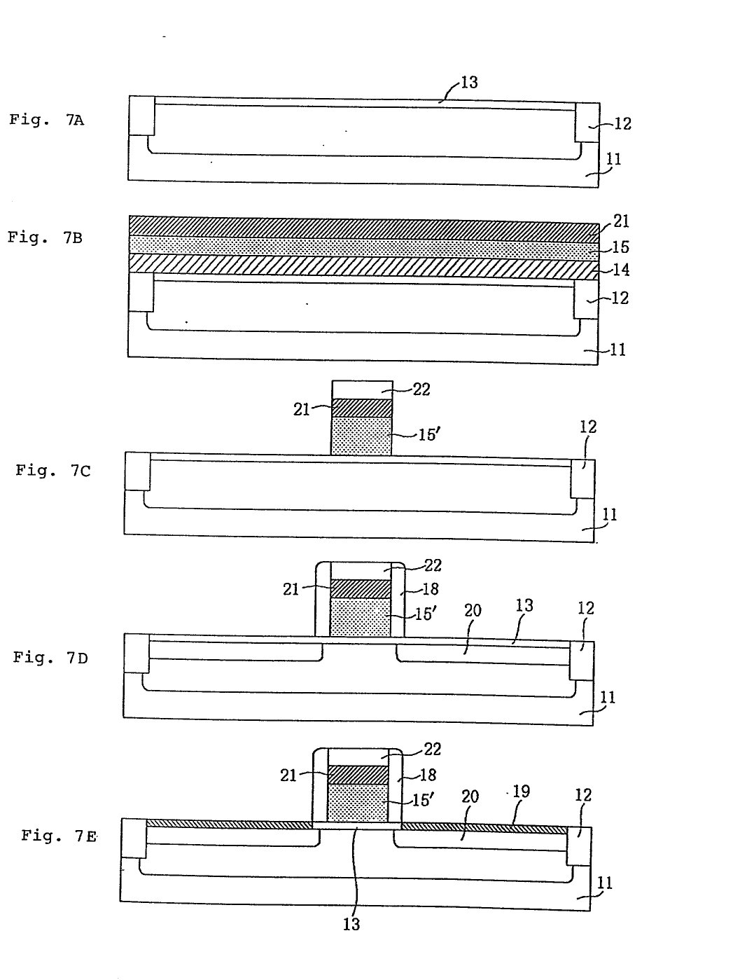

FIGS. 7A to 7E are sectional views of successive steps illustrating a fourth concrete example of the present embodiment.

First, as shown in FIG. 7A, element isolation region 12 is formed on silicon substrate 11 by shallow trench, and a silicon nitride oxide film of 2 nm thick is formed as gate insulating film 13 by a thermal oxide nitriding method.

Then, as shown in FIG. 7B, silicon film 14 of 10 nm thick which is a first layer conductive film and germanium-silicon film 15 of 50 nm thick containing 50% germanium which is a second layer conductive film are deposited each by ordinary CVD, and impurities such as arsenic, phosphor or boron are doped by approximately 1×10¹⁵ cm⁻². Thereafter, conductive multilayer film 21 composed of a titanium nitride film of 2 nm thick and a tungsten film of 10 nm thick is deposited on germanium-silicon film 15. A titanium nitride film is a stable against a silicon film or a silicon-germanium film even upon heat treatment at a high temperature and is not likely to allow a silicidation reaction to occur therewith.

Then, as shown in FIG. 7C, silicon oxide film 22 of 20 nm thick is deposited on the tungsten film by CVD, and then heat treatment for 30 minutes at 800° C. is performed to diffuse germanium in the second layer conductive film into silicon film 14 of the first layer conductive film to form silicon-germanium film 15′. Thereafter, the multilayer conductive films are patterned into a shape of a gate electrode by an ordinary lithography step and etching step.

Then, as shown in FIG. 7D, a silicon oxide film or a silicon nitride film is deposited by 10 nm on the surface of the substrate by CVD, and then, it is etched back to form gate electrode side walls 18. Thereafter, impurities such as arsenic, phosphor or boron are doped by approximately 5×10¹⁵ cm⁻² into the surface region of the silicon substrate by ordinary ion implantation. Furthermore, heat treatment for a short time at 1000° C. is performed to activate the impurities to form source-drain regions 20.

Then, as shown in FIG. 7E, a titanium film is deposited by 7 nm by sputtering, and metal silicide film 19 is formed in a self-aligning manner on source-drain regions 20 by heat treatment for a short time at 700° C. Further, the unreacted metal film is removed by wet etching, thereby completing the manufacturing process of the MIS transistor of the present concrete example.

While, in the present example, titanium nitride is used for the metal nitride film for reaction prevention, the film for reaction prevention need not be limited to this, and some other metal compound film of tantalum nitride, tungsten nitride or the like may be used instead.

### Second Embodiment

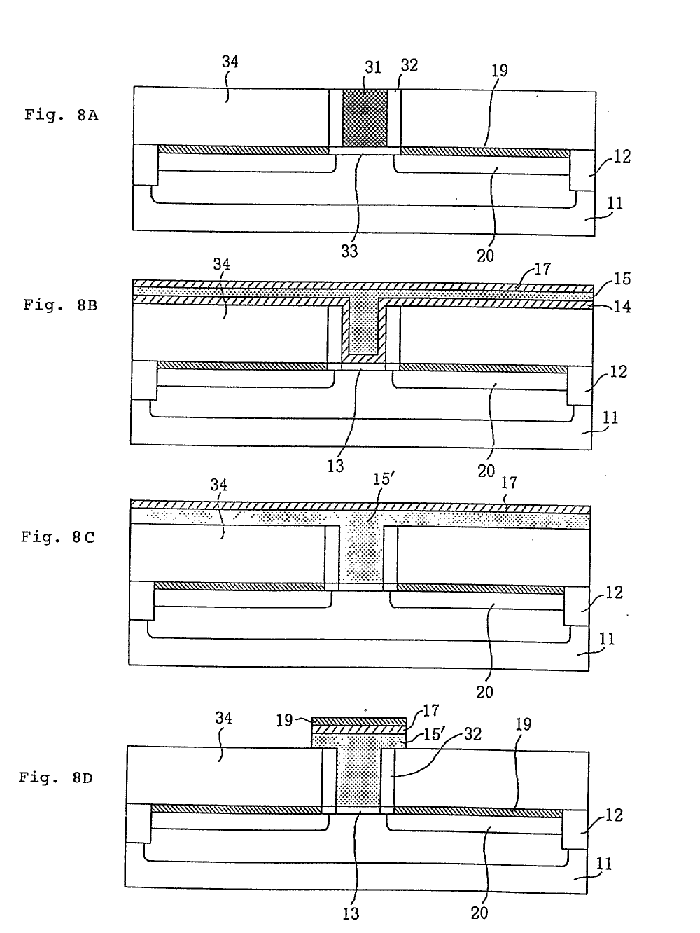

FIGS. 8A to 8D are sectional views of successive steps illustrating a second embodiment of the present invention.

First, as shown in FIG. 8A, a dummy MIS transistor is formed on silicon substrate 11 on which element isolation region 12 is formed. The dummy MIS transistor includes dummy gate electrode 31 having dummy gate electrode side walls 32 formed on side faces thereof, dummy gate insulating film 33, source-drain regions 20 formed on the surface of the silicon substrate, and metal silicide film 19 on source-drain regions 20. The surface of the dummy MIS transistor is covered with interlayer insulating film 34.

Then, as shown in FIG. 8B, dummy gate electrode 31 and dummy gate insulating film 33 below dummy gate electrode 31 are removed, and gate insulating film 13 of the silicon dioxide base, for example, is formed on a channel region of the exposed silicon substrate. Then, silicon film 14 of 2 to 20 nm thick is deposited as a first layer conductive film by chemical vapor phase growth in which silane gas or disilane gas is used.

Then, germanium-silicon film 15 is formed whose germanium concentration is 5 to 50% to 20 to 100 nm thick as a second layer conductive film on silicon film 14 by chemical vapor phase growth in which silane gas or disilane gas and germane gas are used.

Further, large particle size silicon film 17 of 20 to 100 nm thick is deposited as a third layer conductive film on germanium-silicon film 15 by chemical vapor phase growth.

Preferably, the particle size of silicon film 14 is smaller than the film thickness and the particle size of large particle size silicon film 17 is greater than the film thickness.

Then, heat treatment at 600 to 1000° C. is performed to diffuse germanium in the second layer conductive film into the first layer conductive film to form silicon-germanium film 15′ as shown in FIG. 8C.

Then, as shown in FIG. 8D, impurities are doped into the gate electrode by ordinary ion implantation, and the impurities are activated by heat treatment, whereafter a metal film such as a cobalt film is deposited to 1 to 10 nm. Further, metal silicide film 19 is formed on the gate electrode by heat treatment, and then, the unnecessary metal films are removed by etching.

Then, the gate electrode is formed by an ordinary lithography step and etching step, thereby completing the manufacturing process of the MIS transistor of the present embodiment.

### Fifth Concrete Example

FIGS. 8A to 8D are sectional views of successive steps illustrating a fifth concrete example of the present embodiment.

First, as shown in FIG. 8A, element isolation region 12 is formed on silicon substrate 11 by shallow trench. Thereafter, a dummy MIS transistor is formed to include dummy gate insulating film 33 of 2 nm thick formed on silicon substrate 11, dummy gate electrode 31 of 150 nm thick having dummy gate electrode side walls 32 formed on side faces thereof, and source-drain regions 20 having metal silicide film 19 formed on the surface thereof. Further, interlayer insulating film 34 is formed, and the upper surface of dummy gate electrode 31 is exposed by a flattening method such as CMP.

Then, as shown in FIG. 8B, dummy gate electrode 31 and dummy gate insulating film 33 are removed, and a silicon nitride oxide film of 2 nm thick is formed as gate insulating film 13 by a thermal oxide nitriding method. Then, silicon film 14 of 8 nm thick is deposited as a first layer conductive film by ordinary CVD. Then, germanium-silicon film 15 of 70 nm thick containing 40% germanium is formed as a second layer conductive film on silicon film 14, and large particle size silicon film 17 of 50 nm thick is deposited as a third layer conductive film on germanium-silicon film 15 by CVD at a temperature higher than 600° C.

Then, as shown in FIG. 8C, heat treatment at 800° C. for 30 minutes is performed to diffuse germanium in the second layer conductive film into silicon film 14 of the first layer conductive film to form silicon-germanium film 15′.

Then, as shown in FIG. 8D, impurities such as arsenic, phosphor or boron are doped to approximately 5×10¹⁵ cm⁻² into the gate electrode by ordinary ion implantation, and the impurities are activated by heat treatment for a short time at 1000° C. Further, a titanium film is deposited to 7 nm by sputtering, and metal silicide film 19 is formed by heat treatment for a short time at 700° C. Then, the unreacted metal film is removed by wet etching, and the multilayer conductive films are patterned to form a gate electrode, thereby completing the manufacturing process of the MIS transistor of the present example.

### Sixth Concrete Example

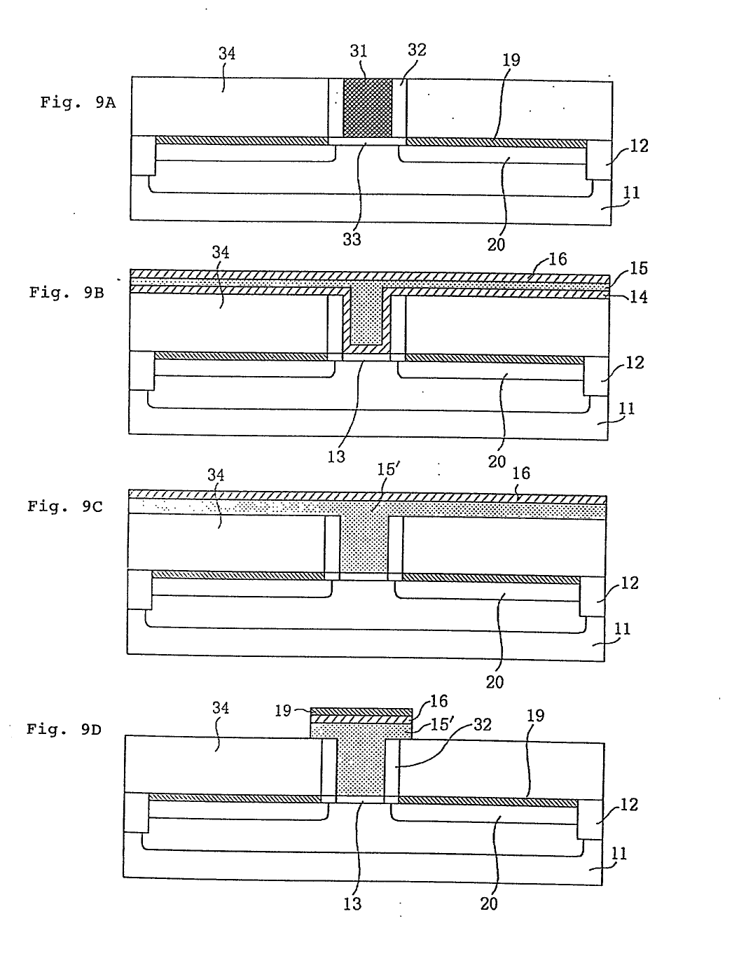

FIGS. 9A to 9D are sectional views of successive steps illustrating a sixth concrete example of the present embodiment.

The steps until interlayer insulating film 34 shown in FIG. 9A is formed are similar to those in the fifth example described hereinabove with reference to FIG. 8A, and therefore, description of them is omitted herein.

Then, as shown in FIG. 9B, dummy gate electrode 31 and dummy gate insulating film 33 are removed, and a silicon nitride oxide film of 2 nm thick which serves as gate insulating film 13 is formed by a radical nitride oxide nitriding method. Then, silicon film 14 of 5 nm thick is deposited as a first layer conductive film by ordinary CVD. Then, silicon-germanium film 15 of 50 nm thick containing 40% germanium is formed as a second layer conductive film on silicon film 14, and amorphous silicon film 16 of 100 nm thick is deposited as a third layer conductive film on silicon-germanium film 15. Amorphous silicon film 16 was deposited at a temperature lower than 550° C. by CVD.

Then, as shown in FIG. 9C, heat treatment at 800° C. for 30 minutes is performed to diffuse germanium in the second layer conductive film into silicon film 14 of the first layer conductive film to form silicon-germanium film 15′.

Then, as shown in FIG. 9D, impurities such as arsenic, phosphor or boron are doped to approximately 5×10¹⁵ cm⁻² into the gate electrode by ordinary ion implantation, and the impurities are activated by heat treatment for a short time at 1000° C. Further, a cobalt film is deposited to 5 nm by sputtering, and metal silicide film (cobalt silicide film) 19 is formed by heat treatment for a short time at 700° C. Finally, the unreacted metal film is removed by wet etching, and the multilayer conductive films are patterned to form a gate electrode, thereby completing the manufacturing process of the MIS transistor of the present concrete example.

### Seventh Concrete Example

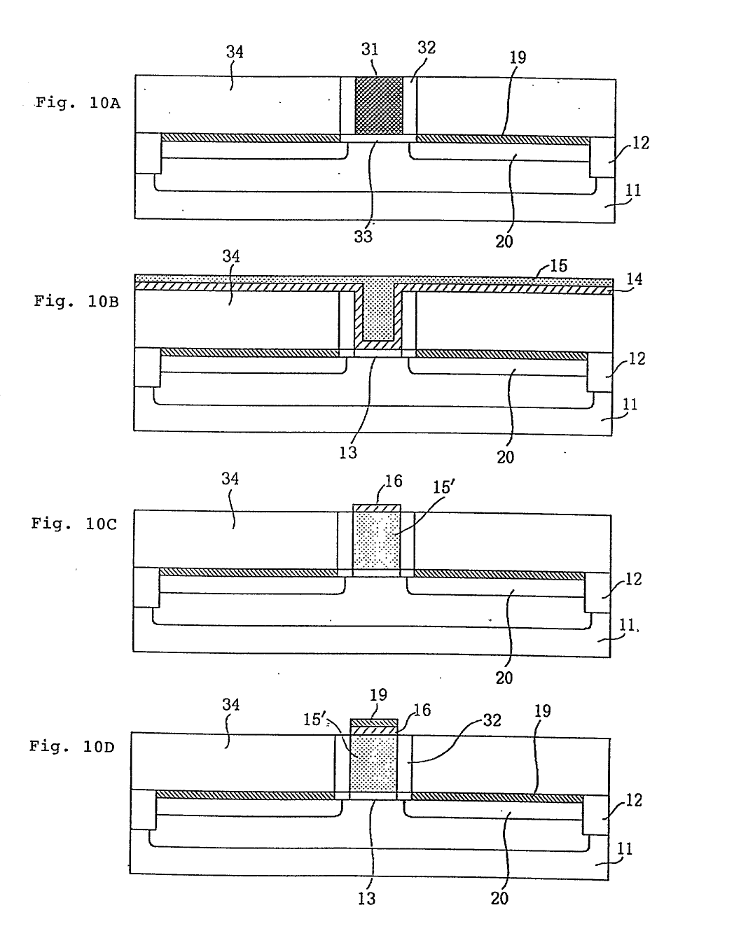

FIGS. 10A to 10D are sectional views of successive steps illustrating a seventh concrete example of the present embodiment.

First, as shown in FIG. 10A, element isolation region 12 is formed on silicon substrate 11 by shallow trench. Thereafter, a dummy MIS transistor is formed to include dummy gate insulating film 33 of 1.5 nm thick formed on silicon substrate 11, dummy gate electrode 31 of 100 nm thick having dummy gate electrode side walls 32 formed on side faces thereof, and source-drain regions 20 having metal silicide film 19 formed on the surface thereof. Further, interlayer insulating film 34 is deposited, and the upper surface of dummy gate electrode 31 is exposed by a flattening method such as CMP.

Then, as shown in FIG. 10B, dummy gate electrode 31 and dummy gate insulating film 33 are removed, and a gate nitride oxide film of 1 nm thick is formed as gate insulating film 13 by a radical oxide nitriding method. Then, silicon film 14 of 10 nm thick is deposited as a first layer conductive film by ordinary CVD. Then, germanium-silicon film 15 of 70 nm thick containing 30% germanium is deposited as a second layer conductive film on silicon film 14.

Then, as shown in FIG. 10C, heat treatment at 800° C. for 30 minutes is performed to diffuse germanium in the second layer conductive film into silicon film 14 of the first layer conductive film to form silicon-germanium film 15′. Thereafter, silicon-germanium film 15′ on interlayer insulating film 34 is removed by etching back, and further, amorphous silicon film 16 is deposited to 20 nm thick on silicon-germanium film 15′, which serves as a gate electrode, by selective CVD.

Then, as shown in FIG. 10D, impurities such as arsenic, phosphor or boron are doped to approximately 5×10¹⁵ cm⁻² into the gate electrode by ordinary ion implantation, and the impurities are activated by heat treatment for a short time at 1000° C. Further, a cobalt film is deposited to 3 nm by sputtering, and metal silicide film 19 is formed by heat treatment for a short time at 700° C. Finally, the unreacted metal films are removed by wet etching, thereby completing the manufacturing process of the MIS transistor of the present concrete example.

### Eight Concrete Example

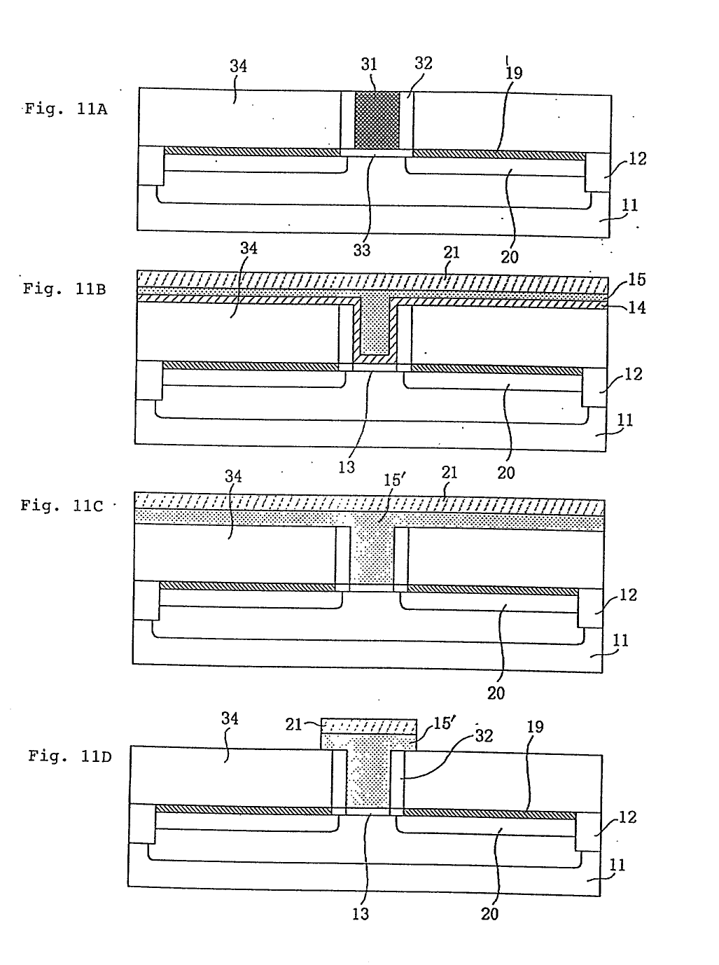

FIGS. 11A to 11D are sectional views of successive steps illustrating an eighth concrete example of the present embodiment.

The steps until interlayer insulating film 34 shown in FIG. 11A is formed are similar to those in the fifth concrete example described hereinabove with reference to FIG. 8A, and therefore, description of them is omitted herein.

Then, as shown in FIG. 11B, dummy gate electrode 31 and dummy gate insulating film 33 are removed, and a silicon nitride oxide film of 2 nm thick which serves as gate insulating film 13 is formed by a thermal oxide nitriding method. Then, silicon film 14 of 10 nm thick is deposited as a first layer conductive film by ordinary CVD. Then, silicon-germanium film 15 of 50 nm thick containing 50% germanium is deposited as a second layer conductive film on silicon film 14, and impurities such as arsenic, phosphor or boron are doped to approximately 5×10¹⁵ cm⁻² by ordinary ion implantation. Further, conductive multilayer film 21 composed of a titanium nitride film of 10 nm thick and a tungsten film of 30 nm thick is formed as a third layer conductive film on silicon-germanium film 15.

Then, as shown in FIG. 11C, heat treatment at 800° C. for 30 minutes is performed to diffuse germanium in the second layer conductive film into silicon film 14 of the first layer conductive film to form silicon-germanium film 15′. At this time, the titanium nitride film does not react with the undercoat silicon-germanium film.

Then, as shown in FIG. 11D, the multilayer conductor films are patterned by an ordinary lithography step and etching step to form a gate electrode, thereby completing the manufacturing process of the MIS transistor of the present concrete example.

It is to be noted that, while a gate insulating film formed from a single film of a silicon oxide film or a silicon nitride oxide film is used in the fifth to eighths concrete examples, it may be replaced by another gate insulating film formed from a multilayer film including a high dielectric constant film.

While preferred embodiments of the present invention have been described using specific terms, such description is for illustrative purposes only, and it is to be understood that changes and variations may be made without departing from the spirit or scope of the following claims.

TABLE 1

| | Diffusion coefficient |
|---|---|
| | of Ge into Si (cm²/sec) |
| Polycrystalline Si film of | (5 to 10) × 10⁻¹⁵ |
| up to 20 nm particle size | |
| Polycrystalline Si film of | (5 to 10) × 10⁻¹⁶ |
| up to 50 nm particle size | |
| Polycrystalline Si film of | (5 to 10) × 10⁻¹⁸ |
| up to 100 nm particle size | |
| Amorphous Si film | (1 to 10) × 10⁻¹⁹ |

What is claimed is:

1. A method of manufacturing a MIS semiconductor device, comprising the steps of:
(1) forming a gate insulating film on a silicon substrate;
(2) forming a silicon thin film on the gate insulating film;
(3) forming a germanium-containing silicon film containing germanium on the silicon thin film; and
(4) performing heat treatment to diffuse the germanium in the germanium-containing silicon film into the silicon thin film.

2. A method of manufacturing a MIS semiconductor device according to claim 1, further comprising the steps of, prior to the step (1), forming a transistor having a dummy gate insulating film, a dummy gate electrode and source-drain regions on a silicon substrate partitioned by an element isolating region, and removing the dummy gate electrode and the dummy gate insulating film, and wherein, in the step (1), the gate insulating film is formed in the region from which the dummy gate insulating film has been removed.

3. A method of manufacturing a MIS semiconductor device according to claim 2, wherein the source-drain regions of the transistor formed prior to the step (1) are covered with an interlayer insulating film of a thickness equal to that of the dummy gate electrode, and most of the interlayer insulating film is left without being removed.

4. A method of manufacturing a MIS semiconductor device according to claim 2, wherein a metal silicide film is formed on the source-drain regions of the transistor formed prior to the step (1).

5. A method of manufacturing a MIS semiconductor device according to claim 1, wherein the gate insulating film is selected from the group consisting of a silicon oxide film, a silicon nitride oxide film, a high dielectric constant film, a multilayer body of a silicon oxide film and a high dielectric constant film, a multilayer body of a silicon nitride oxide film, a high dielectric constant film and a silicon oxide film, and a multilayer body of a silicon nitride oxide film and a high dielectric constant film.

6. A method of manufacturing a MIS semiconductor device, comprising the steps of:
(1) forming a gate insulating film on a silicon substrate;
(2) forming a germanium-containing silicon film containing germanium on the gate insulating film;
(3) forming another silicon film on the germanium-containing silicon film; and
(4) performing heat treatment to diffuse the germanium in the germanium-containing silicon film into the another silicon film.

7. A method of manufacturing a MIS semiconductor device according to claim 6, further comprising the steps of, prior to the step (1), forming a transistor having a dummy gate insulating film, a dummy gate electrode and source-drain regions on a silicon substrate partitioned by an element isolating region, and removing the dummy gate electrode and the dummy gate insulating film, and wherein, in the step (1), the gate insulating film is formed in the region from which the dummy gate insulating film has been removed.

8. A method of manufacturing a MIS semiconductor device according to claim 7, wherein the source-drain regions of the transistor formed prior to the step (1) are covered with an interlayer insulating film of a thickness equal to that of the dummy gate electrode, and most of the interlayer insulating film is left without being removed.

9. A method of manufacturing a MIS semiconductor device according to claim 7, wherein a metal silicide film is formed on the source-drain regions of the transistor formed prior to the step (1).

10. A method of manufacturing a MIS semiconductor device according to claim 6, wherein the gate insulating film is selected from the group consisting of a silicon oxide film, a silicon nitride oxide film, a high dielectric constant film, a multilayer body of a silicon oxide film and a high dielectric constant film, a multilayer body of a silicon nitride oxide film, a high dielectric constant film and a silicon oxide film, and a multilayer body of a silicon nitride oxide film and a high dielectric constant film.

11. A method of manufacturing a MIS semiconductor device, comprising the steps of:
(1) forming a gate insulating film on a silicon substrate within a region partitioned by an element isolation region;
(2) depositing a silicon thin film as a first layer conductive film on the gate insulating film by a chemical vapor phase growth method;
(3) depositing a silicon film containing germanium as a second layer conductive film on the first layer conductive film by a chemical vapor phase growth method;
(4) depositing an amorphous silicon film as a third layer conductive film on the second layer conductive film;
(5) performing heat treatment to diffuse the germanium in the second layer conductive film into the first layer conductive film; and
(6) depositing a metal film on the third layer conductive film and performing heat treatment to cause a silicidation reaction to occur with the metal film to form a silicide film.

12. A method of manufacturing a MIS semiconductor device according to claim 11, wherein the silicon film which is the first layer conductive film has a silicon particle size smaller than the thickness of the deposited film.

13. A method of manufacturing a MIS semiconductor device according to claim 11, wherein the silicon film which is the first layer conductive film has a thickness of 2 to 20 nm.

14. A method of manufacturing a MIS semiconductor device according to claim 11, wherein the gate insulating film and at least the first layer conductive film and the second layer conductive film are formed successively under vacuum.

15. A method of manufacturing a MIS semiconductor device according to claim 11, wherein the third layer conductive film is formed by a chemical vapor phase growth method.

16. A method of manufacturing a MIS semiconductor device according to claim 11, further comprising the steps of, prior to the step (6), forming a gate electrode including the first to third layer conductive films, and forming source-drain regions on the opposite sides of the gate electrode, and wherein, in the step (6), the silicide film is formed also on the source-drain regions.

17. A method of manufacturing a MIS semiconductor device according to claim 11, further comprising the steps of, prior to the step (5) after the step (4), patterning the first to third layer conductive films to form a gate electrode and depositing a side wall insulating film over the entire area, and, after the step (5), etching back the side wall insulating film to form insulating film side walls on the side faces of the gate electrode.

18. A method of manufacturing a MIS semiconductor device according to claim 11, further comprising the steps of, prior to the step (1), forming a transistor having a dummy gate insulating film, a dummy gate electrode and source-drain regions on a silicon substrate partitioned by an element isolating region, and removing the dummy gate electrode and the dummy gate insulating film, and wherein, in the step (1), the gate insulating film is formed in the region from which the dummy gate insulating film has been removed.

19. A method of manufacturing a MIS semiconductor device according to claim 18, wherein the source-drain regions of the transistor formed prior to the step (1) are covered with an interlayer insulating film of a thickness equal to that of the dummy gate electrode, and most of the interlayer insulating film is left without being removed.

20. A method of manufacturing a MIS semiconductor device according to claim 18, wherein a metal silicide film is formed on the source-drain regions of the transistor formed prior to the step (1).

21. A method of manufacturing a MIS semiconductor device according to claim 11, wherein the gate insulating film is selected from the group consisting of a silicon oxide film, a silicon nitride oxide film, a high dielectric constant film, a multilayer body of a silicon oxide film and a high dielectric constant film, a multilayer body of a silicon nitride oxide film, a high dielectric constant film and a silicon oxide film, and a multilayer body of a silicon nitride oxide film and a high dielectric constant film.

22. A method of manufacturing a MIS semiconductor device, comprising the steps of:
(1) forming a gate insulating film on a silicon substrate within a region partitioned by an element isolation region;
(2) depositing a silicon thin film as a first layer conductive film on the gate insulating film by a chemical vapor phase growth method;
(3) depositing a silicon film containing germanium as a second layer conductive film on the first layer conductive film by a chemical vapor phase growth method;
(4) depositing a silicon film having a particle size greater than the thickness of the deposited film as a third layer conductive film on the second layer conductive film;
(5) performing heat treatment to diffuse the germanium in the second layer conductive film into the silicon of the first layer conductive film; and
(6) depositing a metal film on the third layer conductive film and performing heat treatment to cause a silicidation reaction to occur with the metal film to form a silicide film.

23. A method of manufacturing a MIS semiconductor device according to claim 22, wherein the silicon film which is the first layer conductive film has a silicon particle size smaller than the thickness of the deposited film.

24. A method of manufacturing a MIS semiconductor device according to claim 22, wherein the silicon film which is the first layer conductive film has a thickness of 2 to 20 nm.

25. A method of manufacturing a MIS semiconductor device according to claim 22, wherein the silicon film which is the third layer conductive film has a thickness of 20 to 100 nm.

26. A method of manufacturing a MIS semiconductor device according to claim 22, wherein the gate insulating film and at least the first layer conductive film and the second layer conductive film are formed successively under vacuum.

27. A method of manufacturing a MIS semiconductor device according to claim 22, wherein the third layer conductive film is formed by a chemical vapor phase growth method.

28. A method of manufacturing a MIS semiconductor device according to claim 22, further comprising the steps of, prior to the step (6), forming a gate electrode including the first to third layer conductive films, and forming source-drain regions on the opposite sides of the gate electrode, and wherein, in the step (6), the silicide film is formed also on the source-drain regions.

29. A method of manufacturing a MIS semiconductor device according to claim 22, further comprising the steps of, prior to the step (5) after the step (4), patterning the first to third layer conductive films to form a gate electrode and depositing a side wall insulating film over the entire area, and, after the step (5), etching back the side wall insulating film to form insulating film side walls on the side faces of the gate electrode.

30. A method of manufacturing a MIS semiconductor device according to claim 22, further comprising the steps of, prior to the step (1), forming a transistor having a dummy gate insulating film, a dummy gate electrode and source-drain regions on a silicon substrate partitioned by an element isolating region, and removing the dummy gate electrode and the dummy gate insulating film, and wherein, in the step (1), the gate insulating film is formed in the region from which the dummy gate insulating film has been removed.

31. A method of manufacturing a MIS semiconductor device according to claim 30, wherein the source-drain regions of the transistor formed prior to the step (1) are covered with an interlayer insulating film of a thickness equal to that of the dummy gate electrode, and most of the interlayer insulating film is left without being removed.

32. A method of manufacturing a MIS semiconductor device according to claim 30, wherein a metal silicide film is formed on the source-drain regions of the transistor formed prior to the step (1).

33. A method of manufacturing a MIS semiconductor device according to claim 22, wherein the gate insulating film is selected from the group consisting of a silicon oxide film, a silicon nitride oxide film, a high dielectric constant film, a multilayer body of a silicon oxide film and a high dielectric constant film, a multilayer body of a silicon nitride oxide film, a high dielectric constant film and a silicon oxide film, and a multilayer body of a silicon nitride oxide film and a high dielectric constant film.

34. A method of manufacturing a MIS semiconductor device, comprising the steps of:
(1) forming a gate insulating film on a silicon substrate within a region partitioned by an element isolation region;
(2) depositing a silicon thin film as a first layer conductive film on the gate insulating film by a chemical vapor phase growth method;
(3) depositing a silicon film containing germanium as a second layer conductive film on the first layer conductive film by a chemical vapor phase growth method;
(4) performing heat treatment to diffuse the germanium in the second layer conductive film into the silicon of the first layer conductive film;
(5) depositing a silicon film as a third layer conductive film on the second layer conductive film; and
(6) depositing a metal film on the third layer conductive film and performing heat treatment to cause a silicidation reaction to occur with the metal film to form a silicide film.

35. A method of manufacturing a MIS semiconductor device according to claim 34, wherein the silicon film which is the first layer conductive film has a silicon particle size smaller than the thickness of the deposited film.

36. A method of manufacturing a MIS semiconductor device according to claim 34, wherein the silicon film which is the first layer conductive film has a thickness of 2 to 20 nm.

37. A method of manufacturing a MIS semiconductor device according to claim 34, wherein the gate insulating film and at least the first layer conductive film and the second layer conductive film are formed successively under vacuum.

38. A method of manufacturing a MIS semiconductor device according to claim 34, wherein the third layer conductive film is formed by a chemical vapor phase growth method.

39. A method of manufacturing a MIS semiconductor device according to claim 34, further comprising the steps of, prior to the step (6), forming a gate electrode including the first to third layer conductive films, and forming source-drain regions on the opposite sides of the gate electrode, and wherein, in the step (6), the silicide film is formed also on the source-drain regions.

40. A method of manufacturing a MIS semiconductor device according to claim 34, further comprising the steps of, prior to the step (6) after the step (5), patterning the first to third layer conductive films to form a gate electrode, depositing a side wall insulating film over the entire area, and etching back the side wall insulating film to form insulating film side walls on the side faces of the gate electrode.

41. A method of manufacturing a MIS semiconductor device according to claim 34, further comprising the steps of, prior to the step (1), forming a transistor having a dummy gate insulating film, a dummy gate electrode and source-drain regions on a silicon substrate partitioned by an element isolating region, and removing the dummy gate electrode and the dummy gate insulating film, and wherein, in the step (1), the gate insulating film is formed in the region from which the dummy gate insulating film has been removed.

42. A method of manufacturing a MIS semiconductor device according to claim 41, wherein the source-drain regions of the transistor formed prior to the step (1) are covered with an interlayer insulating film of a thickness equal to that of the dummy gate electrode, and most of the interlayer insulating film is left without being removed.

43. A method of manufacturing a MIS semiconductor device according to claim 41, wherein a metal silicide film is formed on the source-drain regions of the transistor formed prior to the step (1).

44. A method of manufacturing a MIS semiconductor device according to claim 34, wherein the gate insulating film is selected from the group consisting of a silicon oxide film, a silicon nitride oxide film, a high dielectric constant film, a multilayer body of a silicon oxide film and a high dielectric constant film, a multilayer body of a silicon nitride oxide film, a high dielectric constant film and a silicon oxide film, and a multilayer body of a silicon nitride oxide film and a high dielectric constant film.

45. A method of manufacturing a MIS semiconductor device, comprising the steps of:
(1) forming a gate insulating film on a silicon substrate within a region partitioned by an element isolation region;
(2) depositing a silicon thin film as a first layer conductive film on the gate insulating film by a chemical vapor phase growth method;
(3) depositing a silicon film containing germanium as a second layer conductive film on the first layer conductive film by a chemical vapor phase growth method;
(4) depositing a silicon film containing germanium and a conductive layer free from a silicidation reaction on the second layer conductive film; and
(5) performing heat treatment to diffuse the germanium in the second layer conductive film into the silicon of the first layer conductive film;

46. A method of manufacturing a MIS semiconductor device according to claim 45, wherein the silicon film which is the first layer conductive film has a silicon particle size smaller than the thickness of the deposited film.

47. A method of manufacturing a MIS semiconductor device according to claim 45, wherein the silicon film which is the first layer conductive film has a thickness of 2 to 20 nm.

48. A method of manufacturing a MIS semiconductor device according to claim 45, wherein the gate insulating film and at least the first layer conductive film and the second layer conductive film are formed successively under vacuum.

49. A method of manufacturing a MIS semiconductor device according to claim 45, further comprising the steps of, prior to the step (6), forming a gate electrode including the first to third layer conductive films, and forming source-drain regions on the opposite sides of the gate electrode, and wherein, in the step (6), the silicide film is formed also on the source-drain regions.

50. A method of manufacturing a MIS semiconductor device according to claim 45, further comprising the steps of, prior to the step (5) after the step (4), depositing a protective insulating film on the conductive layer, and, after the step (5), patterning the first and second layer conductive films and the conductive layer to form a gate electrode.

51. A method of manufacturing a MIS semiconductor device according to claim 45, further comprising the steps of, after the step (5), forming a gate electrode including the first and second layer conductive films and the conductive layer, and forming source-drain regions or source-drain regions and a silicide film on the opposite sides of the gate electrode.

52. A method of manufacturing a MIS semiconductor device according to claim 45, further comprising the steps of, prior to the step (1), forming a transistor having a dummy gate insulating film, a dummy gate electrode and source-drain regions on a silicon substrate partitioned by an element isolating region, and removing the dummy gate electrode and the dummy gate insulating film, and wherein, in the step (1), the gate insulating film is formed in the region from which the dummy gate insulating film has been removed.

53. A method of manufacturing a MIS semiconductor device according to claim 52, wherein the source-drain regions of the transistor formed prior to the step (1) are covered with an interlayer insulating film of a thickness equal to that of the dummy gate electrode, and most of the interlayer insulating film is left without being removed.

54. A method of manufacturing a MIS semiconductor device according to claim 52, wherein a metal silicide film is formed on the source-drain regions of the transistor formed prior to the step (1).

55. A method of manufacturing a MIS semiconductor device according to claim 45, wherein the gate insulating film is selected from the group consisting of a silicon oxide film, a silicon nitride oxide film, a high dielectric constant film, a multilayer body of a silicon oxide film and a high dielectric constant film, a multilayer body of a silicon nitride oxide film, a high dielectric constant film and a silicon oxide film, and a multilayer body of a silicon nitride oxide film and a high dielectric constant film.
